(19) United States
(12) Patent Application Publication
(10) Pub. No.: US 2005/0116768 A1
(43) Pub. Date: Jun. 2, 2005

(54) Amplifier or filter circuit in switched capacitor circuit logic and method for amplifying or filtering signals

(76) Inventor: Jens Sauerbrey, Taufkirchen (DE)

Correspondence Address: Briggs and Morgan, 2400 IDS Center, Minneapolis, MN, 55402, US

(21) Appl. No.: 10/181,901

(22) PCT Filed: Jan. 8, 2001
(86) PCT No.: PCT/DE01/00034

(30) Foreign Application Priority Data
Jan. 21, 2000 (DE) 100025986

(51) Int. Cl. H03B 1/00

(52) U.S. Cl. 327/554

(57) ABSTRACT

An amplifier or filter circuit in switched capacitor circuit logic, comprising an amplifier or filter circuit in switched capacitor circuit logic with a switchable operation amplifier as an input stage of a switched opamp filter or amplifier circuit.

The present invention relates to an amplifier or filter circuit using “switched-capacitor” circuitry and to a method for amplifying or filtering signals using “switched-capacitor” circuits.

The present invention serves for use in “switched-opamp” circuitry, a specific form of “switched-capacitor” (SC) circuitry. This circuitry is described in detail in M. Steyart, “switched-opamp, a Technique for Realizing full CMOS Switched-Capacitor Filters at Very Low Voltages”, ESSCIRC 1993 and in Andrea Baschirotto, Rinaldo Castello and F. Montechi “Design strategy for low-voltage “Switched-Capacitor” -Schaltungstechnik circuits”, Electronic Letters, vol. 30, No. 5, Mar. 3, 1994, for example. This circuitry is used primarily for very low supply voltages. In these instances of employment, the sum of the threshold voltages of p-MOS and n-MOS transistors is sometimes greater than the operating voltage. This means that switch operation even using “transmission gates” is no longer possible over the entire range of the supply voltage. A further development of “switched-capacitor” circuitry, “switched-opamp” technology, shifts the signal levels to such values as allow switch operation of the transistors, or, if signal level shifting is not possible, replaces switches with switchable operational amplifiers.

A weakness which remains in this circuitry is at the input of the circuit. At this point, the input signal needs to be switched using a switch which cannot be replaced. To date, the prior art has cited the following solutions to this:

According to Vinzenzo Peluso et al. “A 900 mV 40-μW ΔΣ Modulator with 77 dB Dynamic Range”, ISSCC98, pp. 68-69, 1998, one solution is to use very small input amplitudes. However, very small signal levels are disadvantageous with regard to noise.

Another solution in accordance with the prior art is provided in Jesper Steengard “Bootstrapped Low-Voltage Analog Switches”, Proceedings for the 1999 IEEE International Symposium on Circuits and Systems, IEEE May/June 1999. On the basis of this prior art, a local gate voltage rise is provided in the input switches. Whether this solution is at all possible, however, depends very much on the critical value of the respective technology.

In addition, DE 42 18 533 C2 and DE 34 41 476 C2 disclose “switched-capacitor” circuits having an operational amplifier, but these can be connected only on a “floating” basis.

It is therefore an object of the present invention to specify an amplifier or filter circuit and a method for amplifying or filtering signals where the advantages of “switched-opamp” technology can be used without the problems with the switches at the input of the circuit arising.

The invention can achieve this object by means of an amplifier circuit using “switched-capacitor” circuitry which is provided with a switchable operational amplifier.

The invention can also achieve the present object by means of a filter circuit using “switched-capacitor” circuitry, where the input side of this filter circuit is preceded by an amplifier having a switchable operational amplifier.

The inventive object can likewise be achieved by virtue of the input side of the amplifier or filter circuit being preceded by a switchable operational amplifier connected up to resistors in such a manner.

Preferably, the total value of the gain of the input stage is chosen to be ≧1 for all these circuits.

In this context, the resistors for connecting up the operational amplifier are preferably made of polysilicon.

Finally, the inventive object can also be achieved by a method for amplifying or filtering signals, where the input signals for these circuits are first supplied to an input stage having a switchable operational amplifier, which input stage shifts the input DC voltage value to such a value as could normally not be processed by the input switch in the following stage.

The invention is explained in detail below with reference to the appended drawings, in which:

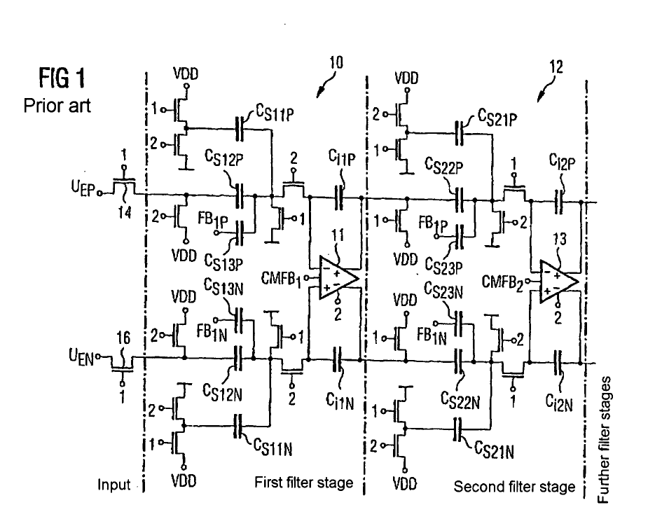

FIG. 1 shows a “switched-opamp” filter circuit based on the prior art;

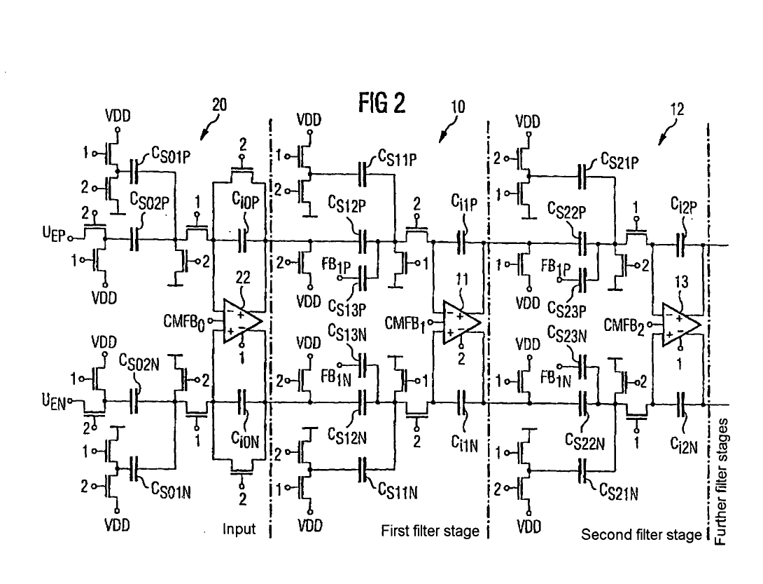

FIG. 2 shows a “switched-opamp” filter circuit preceded by an inventive input amplifier stage having a switchable operational amplifier with aligned DC signal level shifting using “switched-capacitor” technology; and

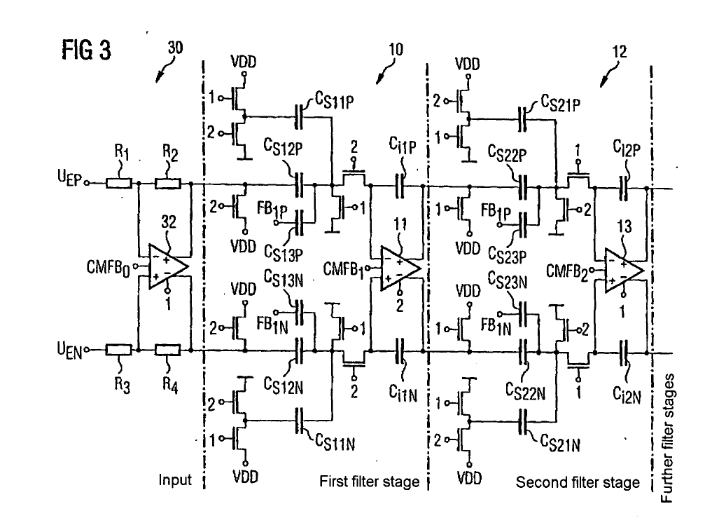

FIG. 3 shows a filter circuit which is inventively preceded by an amplifier circuit having an operational amplifier with aligned DC signal level shifting for operation which is continuous in the time domain.

FIG. 1 shows a typical “switched-opamp” filter circuit comprising a plurality of filter stages. It shows a first filter stage 10 and a second filter stage 12. The problem here is the two transistor switches 14, 16 at the inputs UEP and UEN.

For all the circuits shown in FIGS. 1 to 3, the following parameters will apply:

1. The supply voltage is 1 V (VDD=1 V; VSS=0 V).

2. The threshold voltage for the transistors is approximately 0.6 V, and therefore only voltages between 0 V and 0.3 V and between 0.7 V and 1 V can be switched. Transmission gates and rail-to-rail input stages can therefore be implemented only with an unfeasible level of complexity.

3. The input stage of the operational amplifier comprises 2 p-MOS transistors and can process a common-mode level between 0 V and 0.3 V.

4. The output stage of the operational amplifier has a common-mode level of 0.5 V and can operate in the range between 0.2 V and 0.8 V.

5. If the control signal has been applied to the operational amplifier, the latter's output is on. If it has not been applied, the output is either at high impedance or its supply of current to VSS is at high impedance.

6. If the respective clock phase (“1″ or 2”) has been applied to a transistor, the latter is on.

FIG. 1 shows the input and the first two stages of a typical “switched-opamp” filter circuit. The common-mode input voltage for the operational amplifier is typically VSS. The common-mode output voltage is 0.5 V. The output amplitude of the two operational amplifiers 11 and 13 is 0.6 V peak-peak per path. This voltage value can be achieved by appropriate scaling in all stages. A problem is posed by the MOS transistors 14, 16, used as switches, at the input. Irrespective of whether N-type switches or P-type switches are used, the amplitude in this case needs to be scaled to 0.3 V peak-peak per path. For the prerequisites cited above, an input voltage range between 0 V and 0.3 V is obtained in this case (0.3 V peak-peak per path for 0.15 V common-mode input level).

FIG. 2 shows an embodiment of an input stage 20 provided additionally in accordance with the invention. This input stage 20 comprises an additional amplifier circuit using “switched-capacitor” technology. The additional operational amplifier 22 can be switched in the same way as the further operational amplifiers 11, 13 in the filter stage after the fashion of the “switched-opamp” technology. Preferably, the gain of this operational amplifier 22 is chosen such that a differential voltage of ≦0.6 V is applied to the input of the first filter stage 10. If the differential input signal between UEP and UEN is, by way of example, 60 mV (peak-peak per path for 0 V common-mode input level), then the input stage 20 is preferably proportioned such that it causes a gain of 10.

At the resultant maximum negative input voltage of 30 mV, there is still no expectation of influencing by diode leakage currents. On the other hand, the common-mode input level can also be increased somewhat, for example to +30 mV.

To avoid unfavorable (i.e. very high) capacitance conditions at relatively high gains, a plurality of such inventive input stages 20 can advantageously be connected in series. The reasonable incorporation of the input capacitor in the first filter stage 10 is naturally also useful in order to attain an optimum capacitive load. In the exemplary embodiment shown, this involves the capacitors C_{S12P} and C_{S12N}.

The input stage described is also suitable, in a general sense, for single-ended circuits.

This solution shown in FIG. 2 can be used when the signal needs to be amplified. As FIG. 2 shows, an amplifier using “switched-capacitor” technology is thus modified with a connected operational amplifier 22 for this purpose. This modified “switched-capacitor” amplifier 20 is connected to the input of the first filter stage 10 of the “switched-opamp” filter.

In this case, the amplification is deliberately not performed in the first filter stage 10. A very high gain would in this case firstly result in a very high input capacitance. In addition, for the area requirement, it is much more beneficial to connect a plurality of amplifier stages (described above) with a lower gain one behind the other (the capacitors determine the area, the capacitance ratio determines the gain, and there is a noise limit for reducing the capacitance values).

In the embodiment shown in FIG. 2, a “switched-capacitor” amplification stage is thus aligned with the “switched-opamp” circuitry by introducing the switchable operational amplifier 22, so that said “switched-opamp” circuitry, as a preamplification stage, can solve the problem of the input switches 14, 16 in the “classical” “switched-opamp” circuitry shown in FIG. 1.

FIG. 3 shows another inventive embodiment of an input stage, in this case denoted by 30, which is again connected upstream of the first filter stage 10 in the “switched-opamp” filter circuit shown in FIG. 1. This input stage 30 likewise consists of an additional operational amplifier 32. In this case, however, this operational amplifier 32 is connected to up to four resistors R₁ . . . R₄. These resistors can preferably be in the form of “polysilicon” resistors.

The additional operational amplifier 32 can be switched in the same way as the operational amplifiers 11, 13 in the filter stages 10, 12 using “switched-opamp” technology. If R₁=R₂ and R₃=R₄ are chosen, then the gain of the input stage 30 is −1. An input voltage of 0.6 V peak-peak thus in turn produces an input voltage of 0.6 V peak-peak at the input of the first filter stage 10. In the exemplary embodiment shown in FIG. 3, the input amplitude can thus be doubled, because the conventional input stage based on the prior art (FIG. 1) would have allowed only an input voltage of 0.3 V peak-peak.

If a common-mode input level of 0 V is used (e.g. as a result of capacitive coupling), then the common-mode input voltage of the operational amplifier 32 is 0.25 V. This common-mode level can be processed well using a P-MOS input stage.

In this case, the maximum negative voltage of −0.3 V arising for a common-mode input level of 0 V is present across a resistor which, by way of example, can be in the form of a polysilicon resistor, and said maximum negative voltage therefore brings about no leakage currents (i.e. no parasitic diode has a voltage applied to it in the forward direction).

This circuit can advantageously also be used for signal amplification. In this case, R₂>R₁. The source used in this case is, by way of example, a differential microphone, which is in turn connected to VSS, for example. The higher the gain chosen, the lower is the resultant common-mode input voltage for the operational amplifier.

The input stage described is also suitable, in a general sense, for single-ended circuits.

On the basis of this embodiment of the invention which is shown in FIG. 3, the input signal is connected not directly but rather via a switchable operational amplifier 32 to the input of the first filter stage 10 using “switched-opamp” technology.

In the case of this inventive solution shown in FIG. 3, an amplifier stage 30 is thus aligned with the “switched-opamp” circuitry by introducing a switchable operational amplifier 32 with aligned DC signal level shifting.

1. An electronic circuit having a circuit using “switched-opamp” circuitry, and having a nonintegrating amplifier circuit which is connected to an input of the circuit using “switched-opamp” circuitry and has a switchable operational amplifier (22; 32).

2. The electronic circuit as claimed in claim 1, in which the circuit using “switched-opamp” circuitry is set up as an amplifier circuit.

3. The electronic circuit as claimed in claim 1, in which the circuit using “switched-opamp” circuitry is set up as a filter circuit.

4. The electronic circuit as claimed in claim 3, in which the switchable operational amplifier (22; 32) connected upstream of the input side of the filter circuit (10) is connected up to nonreactive resistors (R₁ . . . R₄) such that the total value of the gain of this input stage (30) is >1.

5. The electronic circuit as claimed in claim 4, in which the operational amplifier (22; 32) connected upstream can be supplied with the input signals using capacitive or resistive coupling.

6. The electronic circuit as claimed in claim 4 or 5, in which the nonreactive resistors (R₁ . . . R₄) are made of polysilicon.

7. A method for amplifying or filtering signals using “switched-opamp” circuits which are supplied with very low voltages, where the input signals for these circuits are first supplied to a nonintegrating input stage having a switchable operational amplifier, which nonintegrating input stage shifts or amplifies the input DC voltage value to such a value as could normally not be processed by the input switch in the following stage.
